(19) United States
(12) Patent Application Publication
(10) Pub. No.: US 2018/0062062 A1
(43) Pub. Date: Mar. 1, 2018

(54) ADAPTIVE ELECTROMECHANICAL SHUNT SYSTEM, RELATED ADAPTATION LAW CIRCUIT AND METHOD FOR CONTROLLING VIBRATIONS OF STRUCTURES

(71) Applicant: Jorge Augusto de Bonfim Gripp, Sao Jose dos Campos/SP (BR)

(72) Inventor: Jorge Augusto de Bonfim Gripp, Sao Jose dos Campos/SP (BR)

(21) Appl. No.: 15/249,142

(22) Filed: Aug. 26, 2016

(51) Int. Cl. H01L 41/04; G01H 11/08

(52) U.S. Cl. CPC H01L 41/042; G01H 11/08

(57) ABSTRACT

Disclosed herein is an adaptive system that converts vibration in mechanical structures into electrical energy using a transducer having piezoelectric properties. The electrical energy generated is then converted into heat loss in an electrical circuit comprising: an adaptive inductance that autonomously changes its value by comparing the phase difference of the vibration velocity and the current flowing through the shunt circuit; a resistance to convert electrical energy into heat loss; and a synthetic negative capacitance to enhance the vibration attenuation.

### TECHNICAL FIELD

The present invention relates to an adaptive electromechanical shunt system for controlling vibrations of structures. More specifically, the present invention relates to a shunt damping system comprising components with piezoelectric properties that is able to autonomously and deliver, in an analog manner, optimum vibration attenuation to a structure.

### BACKGROUND

Mechanical structures are subjected to vibration effects due to operational or environmental forces, which can cause mechanical failure, limit the precision of mechanical equipment, and create noise. The consequences can vary from economic loss to personal injury or death. Devices such as precision machine tools, precision robots, and telescopes require low vibrations for operation. Noise and vibration is detrimental to comfort in transportation vehicles and industrial environment. In addition, structural vibrations in aircraft and rotorcraft applications may increase interior cabin noise levels and accelerate material fatigue.

The current trend toward lightweight structures, as a direct reaction to the rising demands for more efficient and ecologically friendly vehicles, leads to new challenges on vibration control technology. On the other hand, traditional approaches to vibration reduction usually increase the mass of the mechanical structure, by techniques such as stiffening the structure, adding mechanical dampers or dynamic vibration absorbers, covering the structure with viscoelastic damping material, or adding acoustic shielding and vibration isolators to shield the structure from the environment.

As an alternative to passive damping materials, piezoelectric transducers together with appropriate electrical circuits have been proposed as vibration dissipation devices. Piezoelectricity is a phenomenon exhibited by certain material in which the materials can generate electrical energy when subjected to mechanical energy (e.g., strained), or generate mechanical energy when subjected to electrical energy, or both. Significant piezoelectric effect can be observed in polycrystalline ferroelectric ceramics such as lead zirconate titanate (PZT) or barium titanate and polymers such as polyvinylidene fluoride (PVDF).

Conventional vibration control using piezoelectric transducers is implemented mostly in an active arrangement: an actuator generates forces to annul the vibrations based on a signal from an accelerometer, velocity or strain sensor. This arrangement is bulky, expensive and demands considerable power-supply, since it requires amplifiers, filters, A/D (analog-to-digital) and D/A (digital-to-analog) converters, and a controller implemented on a microprocessor or computer. As a substitute for this large electronic instrumentation, the piezoelectric “shunt damping” field was developed, which consists of using a piezoelectric transducer to transform mechanical vibration energy into electrical energy, which is dissipated as heat in an electrical circuit.

Resonant circuits, consisting of a resistance (R) and an inductance (L) connected in series (RL-shunt), were the first efficient circuits for piezoelectric shunt damping. The electrical resonance of the RL-shunt together with the piezoelectric capacitance is tuned to one modal frequency in order to dampen the vibrations of this particular mode. At this frequency, the effect of the inductance is to cancel out the inherent capacitive impedance of the piezoelectric transducer in order to maximize the energy transfer that is dissipated in the resistor. There is also a method disclosed in U.S. Pat. No. 4,158,787 in which a negative capacitance circuit is used to cancel out the piezoelectric transducer capacitance, but this circuit can easily become unstable with small variations in the piezoelectric transducer capacitance or negative capacitance values.

Unfortunately, currently known resonant shunts are effective only in narrow frequency bands and their performance drops severely with a mistuning of the electrical resonance frequency. For this reason, one of the key challenges to the introduction of this piezoelectric technology into real applications of industrial interest is to guarantee robustness against system parameter variations, such as variations in structural modal frequencies and transducer capacitance.

Previously, bulky arrangements were used to adapt the electrical resonance frequency of resonant shunts (see, for example, U.S. Pat. No. 6,538,401, which uses a computer). On the other hand, the embodiments of the present disclosure as described subsequently herein require small power for operation, and the implemented circuit is of low weight and small size.

### BRIEF SUMMARY

An object of the present invention is to provide a novel control device to tune the shunt circuit inductance according to the mechanical vibration frequency. This circuit uses a second piezoelectric transducer positioned as a sensor and simple analog electronic components to implement the adaption law of a voltage-controlled inductance.

Another object of this invention is to provide a synthetic negative capacitance to enhance the vibration attenuation. The association of a negative capacitance together with the piezoelectric transducer capacitance in order to modify the total circuit capacitance increases the efficiency of the coupling between the mechanical structure and the electrical circuit and, consequently, enhances the vibration attenuation provided by the piezoelectric absorber.

### BRIEF DESCRIPTION OF THE DRAWINGS

The following description of the drawings is merely exemplary and is not intended to limit the present disclosure, its application or uses.

FIG. 1 depicts an exemplary mechanical structure in the form of a shell excited by an external disturbance force.

FIG. 2 illustrates a voltage-controlled inductance with equivalent inductance.

FIG. 3 shows that the variable resistance is obtained using a junction gate field-effect transistor, with drain-source channel resistance depending on the control voltage.

FIG. 4 illustrates a synthetic negative capacitance with equivalent capacitance that is connected to the piezoelectric transducer through the electrical terminal.

FIG. 5 presents the adaptation law circuit comprising: three low-pass filters, a multiplier, an integrator, and an attenuator.

FIG. 6 shows an experimental measurement of inductance and how it changes responsive to the applied control voltage.

FIGS. 7A and 7B illustrate the ability of the piezoelectric shunt damping system to autonomously adapt itself to deliver optimum, or at least improve vibration attenuation even if the natural frequency of the host structure changes.

FIG. 8 shows that the vibration attenuation is enhanced by adding a synthetic negative capacitance into the piezoelectric shunt damping system.

### DETAILED DESCRIPTION

The above features and advantages and other features and advantages of the invention are readily apparent from the following description of the invention when taken in connection with the accompanying exemplary drawings.

In a first embodiment, the present disclosure is an adaptive electromechanical shunt system for controlling vibrations of a structure. The structure may be, for example, a vehicle, a spaceship, an airplane, a building, a telescope, a microscope or any other structure that may be subjected to, or that generates vibrations.

The adaptive electromechanical shunt system of the present disclosure may comprise a transducer with piezoelectric properties 104 mechanically attached to a structure 101. Preferably, the transducer with piezoelectric properties 104 is mechanically attached to the structure 101 by welding, bonding or fixed by any other mean that allows the transducer with piezoelectric properties 104 to be mechanically attached to the structure 101.

The transducer with piezoelectric properties 104 may be mechanically attached to the structure 101 so as to transform mechanical vibration energy of the structure 101 into electrical energy.

Optionally, the adaptive electromechanical shunt system may comprise an element 108 that dissipates electrical energy.

The adaptive electromechanical shunt system of the present disclosure may comprise means for autonomously, in an analog manner, controlling vibrations of a structure independently of the normal variations of mechanical and electrical properties of the shunt system components and of changes of the operating conditions.

The adaptive electromechanical shunt system of the present disclosure works autonomously in the sense that it does not have or need external means for controlling the vibration.

Moreover, the adaptive electromechanical shunt system of the present disclosure works in an entirely analog manner, since it does not use a computer or any other digital means for generating the control voltage, which controls the vibration.

Normal variations of mechanical and electrical properties of the shunt system components are, for example, the normal variation of the component manufacturer specifications.

Changes of the operating conditions may be, but are not limited to, for example, changes in temperature, such as in the structure of an airplane, subjected to a temperature of up to 40° C. on the ground and, for example, −40° C. at flight altitude. Temperature variations cause changes in fundamental factors in the circuit, for example, capacitance and structural properties of the components, which can influence the vibration frequency.

The adaptive electromechanical shunt system of the present disclosure may further comprise a synthetic negative capacitance 400. Such a synthetic negative capacitance 400 may be connected to the electromechanical component circuit and changes the total equivalent capacitance and enhance the vibration attenuation of the structure 101.

The means for autonomously, and in an analog manner, controlling vibrations of an adaptive electromechanical structure, independently of the normal variations of mechanical and electrical properties of the shunt system components and of changes of operating conditions may comprise a transducer 109, a variable inductance circuit 200, and an adaptation law circuit 500.

In one aspect of the present disclosure, the transducer 109 senses the mechanical vibration of the structure 101.

In another aspect, the variable inductance circuit 200 changes its value controlled by a voltage 112.

In an example embodiment, the adaptation law circuit 500 autonomously generates the control voltage 112 in an analog manner based on the phase difference between the inductor voltage 107 and the voltage 110. According to an alternative embodiment of the present disclosure, the transducer 109 of the adaptive electromechanical shunt system may be a transducer with piezoelectric properties.

In an example embodiment, the electromechanical shunt system of the present disclosure comprises a transducer with piezoelectric properties mechanically attached to a structure and an element that dissipates electrical energy. The electromechanical shunt system comprises means for autonomously, and in an analog manner, adapting its resonance frequency to control vibrations of a structure independently of the normal variations of mechanical and electrical properties of the shunt system components and of changes of the operating conditions.

In another embodiment, the present disclosure includes an adaptation law circuit 500 that autonomously, and in an analog manner, generates a control voltage based on adjusting the relative phase difference between the vibrational velocity and shunt circuit current, which controls the inductance of a circuit to control vibrations.

The adaptation law circuit may comprise one or more, for example, two or three low-pass filters (e.g., low-pass filters 501, 502, and 504), a multiplier 503, an integrator 505, and an attenuator 506. In other embodiments, the adaptation law circuit may comprise more or less than three low-pass filters, one or more multipliers, one or more integrators and one or more attenuators.

In another embodiment, the present disclosure includes a method for controlling vibrations of a structure independently of the normal variations of mechanical and electrical properties of the structure, shunt system components and changes in operating conditions. The vibrations of the structure may be autonomously controlled in an analog manner by the method for controlling vibrations of the present disclosure.

In another embodiment, the vibrations of the structure may be autonomously controlled, in an analog manner, by the adaptive electromechanical shunt system according to the present disclosure.

The method for controlling vibrations of a structure according to embodiments of the present disclosure may comprise the basic steps of:
employing vibrations of the structure to generate, through elements 104 and 109, voltages 107 and 110, respectively; and
using the phase difference between the voltage 110 and voltage 107 to autonomously, and in an analog manner, generate a control voltage 112, which controls the inductance 200, wherein the vibrations of the structure are controlled by the electromechanical action of element 104.

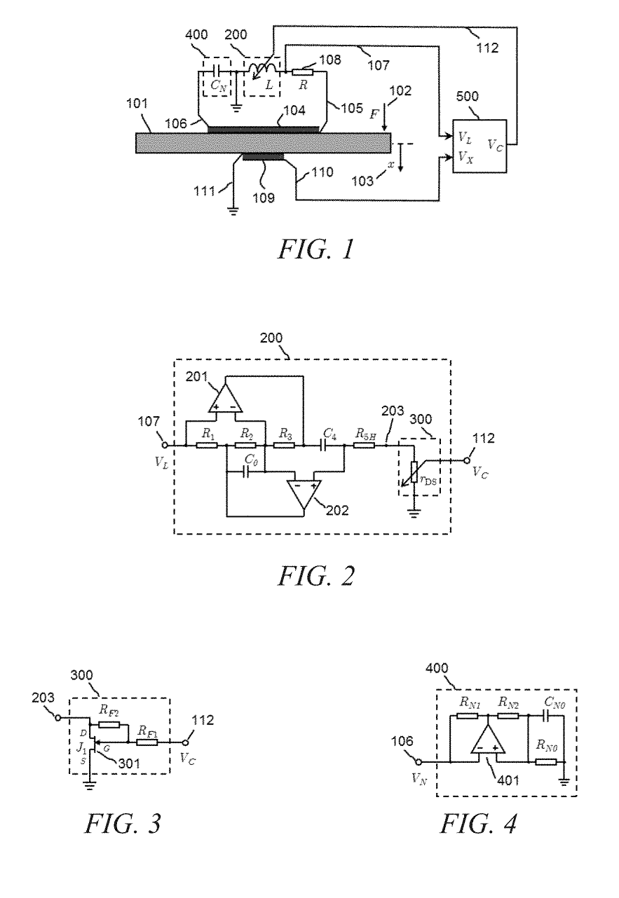

FIG. 1 presents an exemplary mechanical structure in the form of a shell 101 excited by an external disturbance force F 102. The external disturbance 102 causes a vibration displacement x 103, which is damped by the presence of a piezoelectric transducer 104 bonded on the structure 101 and having a pair of electrical terminals 105 and 106. The piezoelectric transducer 104 is connected in series through the electrical terminal 105 to a damping resistor R 108, a voltage-controlled inductance L 200, and synthetic negative capacitance C_{N} 400. An electrical signal indicative of the vibration displacement x 103 may be obtained by a second transducer 109 bonded on the structure 101 and having a grounded electrical terminal 111 and an electrical terminal 110 with voltage V_{X}.

Referring now to FIG. 2, a voltage-controlled inductance 200 is presented with equivalent inductance L=R₁R₃(R₅+r_{DS})/R₂. The inductance value is adjusted by changing the resistance r_{DS} 300 using the voltage V_{C} 112. A DC (direct current) power supply (+V_{CC}, V_{CC}) provides energy to the operational amplifiers 201 and 202.

In FIG. 3, the variable resistance r_{DS} 300 is obtained using a junction gate field-effect transistor (JFET) 301, with drain-source channel resistance depending on the control voltage V_{C} 112. Two resistors R_{F1}=R_{F2} are added into the circuit to linearize the dependence of the JFET resistance r_{DS} 300 on the control voltage V_{C} 112.

FIG. 4 illustrates a synthetic negative capacitance 400 with equivalent capacitance

C_{N}=−C_{N0}(R_{N2}/R_{N1})

that is connected to the piezoelectric transducer 104 through the electrical terminal 106. Practical implementation requires an extra resistor with high resistance, for instance, R_{N0}=1 MΩ. A DC power supply (+V_{CC}, V_{CC}) provides energy to the operational amplifier 401.

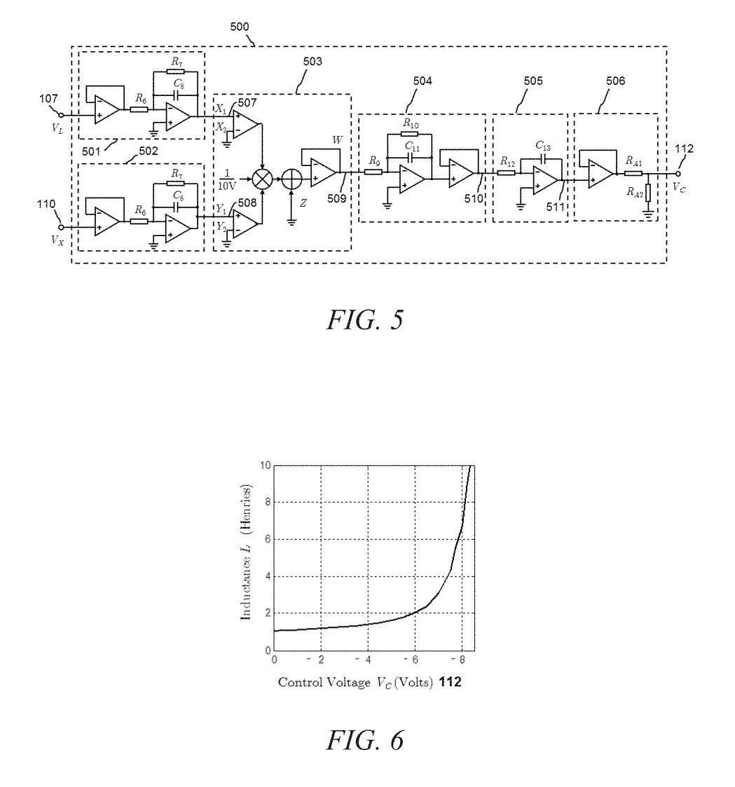

FIG. 5 presents the adaptation law circuit 500 comprising: three low-pass filters 501, 502, and 504, a multiplier 503, an integrator 505, and an attenuator 506. The circuit 500 uses the property that inductance 200 is optimally tuned when the phase difference φ is 90 degrees (π/2 radians) between the inductor voltage V_{L} 107 and the voltage V_{X} 110. Electrical signals V_{L} 107 and V_{X} 110 are firstly filtered using low-pass filters 501 and 502, respectively, in order to avoid measurement noise. Both filtered signals 507 and 508 are then multiplied using a multiplier 503, for example, the integrated circuit AD633. The resulting signal 509 is filtered using the low-pass filter 504 to compute its DC (direct current) component 510, which is proportional to the cosine of the phase difference φ. When the inductance 200 is optimally tuned, the cos(φ)is zero and voltage 509 is zero, however, when inductance 200 is mistuned, voltage 509 is integrated using integrator circuit 505. The integrated signal 511 is proportionally reduced using the attenuator 506, resulting on the control voltage V_{C} 112, which controls the inductance 200.

FIG. 6 shows an experimental measurement of inductance L 200 and how it changes due to the applied control voltage V_{C} 112.

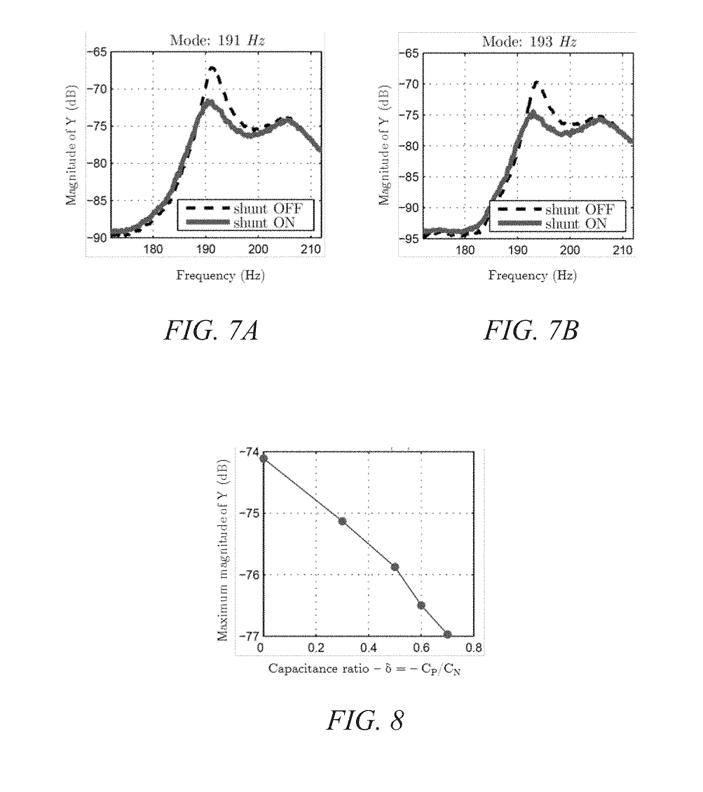

FIGS. 7A and 7B illustrate the ability of the piezoelectric shunt damping system to autonomously adapt itself to deliver improved, or even optimum vibration attenuation even if the natural frequency of the host structure 101 changes. In this measurement, the structure 101 is an aluminum shell clamped on a steel framework and the piezoelectric transducers 104 and 109 are made of PZT. The measured transfer function from the excitation force F 102 to the vibration velocity, which is the time derivative of the displacement x 103, is the mobility Y=vibration velocity/excitation force. The magnitude of Y is presented in decibels (dB), where 0 dB is equivalent to 1 m.s⁻¹N⁻¹. In the experiment illustrated in FIG. 7B, two masses are glued on the shell 101, near to its edge. This modification in the structure increases its natural frequency from 191 in FIG. 7A to 193 Hz in FIG. 7B. The vibration attenuation due to the piezoelectric shunt damping system is seen in FIGS. 7A and 7B by comparing when the system is off (dashed line) with when it is on (solid line). As can be seen, the piezoelectric shunt damping system reduces by 5 dB the mobility magnitude in both figures, despite the natural frequency variation. In response to the frequency increase, the circuit adapted the control voltage V_{C} 112 from −3.4 in FIG. 7A to −3.0 V in FIG. 7B.

FIG. 8 shows that the vibration attenuation is enhanced by adding a synthetic negative capacitance 400 into the piezoelectric shunt damping system. The ratio of the intrinsic capacitance of the piezoelectric transducer 104 to the negative capacitance C_{N} 400 is named capacitance ratio δ. As the maximum magnitude of the mobility Y is achieved at 191 Hz, a sinusoidal excitation matching this frequency is used to evaluate the damping performance. The vibration decreases 3 dB when the capacitance ratio is changed from zero to δ=−0.7. The inductance L adapts itself according to the total capacitance value variation in order to maintain the same electric resonance frequency. As a result, the piezoelectric shunt damping system reduces the maximum vibration magnitude by 5 dB with capacitance ratio δ=0 and 8 dB with capacitance ratio δ=−0.7.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise.

When used in this specification, specification of the presence of stated features, integers, steps, operations, elements, and/or components does not preclude the presence or addition of one more other features, integers, steps, operations, element components, and/or groups thereof.

Similarly, the activities of the methods described herein may be performed in a different order, or steps may be added, deleted or modified. All such variations are contemplated by the present disclosure.

The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiments described were chosen and described in order to best explain the principles of the disclosure and the practical application, and to enable others of ordinary skill in the art to understand the disclosure for various embodiments with various modifications as are suited to the particular use contemplated.

While example embodiments of the present invention have been described in detail herein, it will be understood by those skilled in the art that various changes may be made and equivalents may be substituted for elements thereof without departing from the scope of the invention. In addition, many modifications may be made to adapt a particular situation or material to the teachings of the disclosure without departing from the essential scope thereof. Therefore, it is intended that the claimed invention not be limited to the particulars of the described embodiments.

What is claimed is:

1. An adaptive electromechanical shunt system for controlling vibrations of a structure, comprising:
a transducer with piezoelectric properties mechanically attached to a structure to transform mechanical vibration energy of the structure into electrical energy; and
an element that dissipates electrical energy;
wherein the adaptive electromechanical shunt system comprises means for autonomously controlling, in an analog manner, vibrations of a structure independently of the normal variations of mechanical and electrical properties of the shunt system components and of changes of the operating conditions.

2. The adaptive electromechanical shunt system of claim 1, wherein the means for autonomously controlling, in an analog manner, vibrations of a structure independently of the normal variations of mechanical and electrical properties of the shunt system components and of changes of operating conditions comprise:
a transducer to sense the mechanical vibration of the structure;
a variable inductance circuit, which changes its value controlled by a control voltage;
a synthetic negative capacitance connected to the electromechanical component circuit to change the total equivalent capacitance and enhance the vibration attenuation of the structure; and
an adaptation law circuit, which autonomously generates the control voltage in an analog manner based on the phase difference between an inductor voltage of the variable inductance circuit and a terminal voltage of the transducer.

3. The adaptive electromechanical shunt system of claim 1, wherein the transducer is a transducer with piezoelectric properties.

4. An adaptation law circuit that autonomously generates a control voltage in an analog manner responsive to adjustment of a relative phase difference between a vibrational velocity and a shunt circuit current, which controls an inductance of a circuit for controlling vibrations.

5. The adaptation law circuit of claim 4, further comprising one or more low-pass filters, a multiplier, an integrator, and an attenuator.

6. A method for controlling vibrations of a structure independently of the normal variations of mechanical and electrical properties of the structure, components of an adaptive electromechanical shunt system attached to the structure, and changes in operating conditions, wherein the vibrations of the structure are autonomously controlled in an analog manner using the adaptive electromechanical shunt system, the adaptive electromechanical shunt system comprising:
a transducer with piezoelectric properties mechanically attached to a structure to transform mechanical vibration energy of the structure into electrical energy; and
an element that dissipates electrical energy;
wherein the adaptive electromechanical shunt system comprises means for autonomously controlling, in an analog manner, vibrations of a structure independently of the normal variations of mechanical and electrical properties of the shunt system components and of changes of the operating conditions.

7. The method of claim 6, further comprising:
employing vibrations of the structure to generate, through a transducer with piezoelectric properties and a second transducer, inductor voltage V_{L} and voltage V_{X}, respectively; and
using a phase difference between the voltage V_{X} and inductor voltage V_{L} to autonomously, and in an analog manner, generate a control voltage, which controls an inductance of a variable inductance circuit coupled with the transducer with piezoelectric properties, wherein the vibrations of the structure are controlled by electromechanical action of the transducer with piezoelectric properties.
